(19) United States
(12) Patent Application Publication
(10) Pub. No.: US 2017/0200843 A1
(43) Pub. Date: Jul. 13, 2017

(54) RESIN-CONTAINING SOLAR CELL MODULE

(71) Applicant: Panasonic Intellectual Property Management Co., Ltd., Osaka (JP)

(72) Inventors: Junpei IRIKAWA, Osaka (JP); Naoto IMADA, Osaka (JP); Tasuku ISHIGURO, Osaka (JP); Hiroshi KANNO, Osaka (JP)

(21) Appl. No.: 15/472,618

(22) Filed: Mar. 29, 2017

Related U.S. Application Data
(63) Continuation of application No. PCT/JP2015/003823, filed on Jul. 29, 2015.

(30) Foreign Application Priority Data
Sep. 30, 2014 (JP) 2014-201840

(51) Int. Cl. H01L 31/048; H01L 31/05; H01L 31/055; H01L 31/049

(52) U.S. Cl. CPC H01L 31/0481; H01L 31/049; H01L 31/0516; H01L 31/0508; H01L 31/055

(57) ABSTRACT

A solar cell module includes solar cells. encapsulants are layered on surfaces of the solar cells. A glass substrate is layered on the encapsulants. The solar cell module further includes an epoxy resin-containing member. Each encapsulant includes the ultraviolet ray-absorbing member. The ultraviolet ray-absorbing member sets the transmittance to 1% or less at the wavelengths ranging from 300 to 360 nm.

### CROSS-REFERENCE TO RELATED APPLICATION

This application is based upon and claims the benefit of priority from the prior Japanese Patent Application No. 2014-201840, filed on Sep. 30, 2014, the entire contents of which are incorporated herein by reference.

### BACKGROUND

1. Field

The disclosure relates to a solar cell module. Particularly, the disclosure relates to a resin-containing solar cell module.

2. Description of the Related Art

A solar cell module for converting sunlight into electric energy produces clean renewable energy. In the solar cell module, an encapsulant is disposed between solar cells and a surface covering layer.

It is desirable that the encapsulant should perform as an adhesive and protect the solar cell from scratches or impact caused from an outside thereof and shut off ultraviolet rays to some extent to improve weatherability. (refer to JP hei7-169984 A, JP hei8-139347 A and JP 2006-66682 A, for example).

A member included in a solar cell module may contain epoxy resin. This epoxy resin is degraded by ultraviolet rays.

### SUMMARY

The present invention has been made in light of such a situation, and an object of the present invention is to provide a technique for preventing the resin included in the solar cell module from being degraded by the ultraviolet rays.

In order to solve the problem, a solar cell module according to an aspect includes a solar cell, an encapsulant layered on surfaces of the solar cell, a protective member layered on the encapsulant, and an epoxy resin-containing member. The encapsulant includes an ultraviolet ray-absorbing member. The ultraviolet ray-absorbing member sets transmittance to 1%or less at wavelengths ranging from 300 to 360 nm.

Another aspect is also a solar cell module. This solar cell module includes a protective member, a back sheet opposing the protective member, an encapsulant disposed between the back sheet and protective member, and a solar cell sealed by the encapsulant. The back sheet contains resin and the encapsulant includes an ultraviolet ray-absorbing member. The ultraviolet ray-absorbing member sets the transmittance to 1% or less at wavelengths ranging from 300 to 360 nm.

Still another aspect is a solar cell module. This solar cell module includes a solar cell, an encapsulant layered on surfaces of the solar cell, a protective member layered on the encapsulant, and a polyethylene terephthalate resin-containing member. The encapsulant includes an ultraviolet ray-absorbing member. The ultraviolet ray-absorbing member sets transmittance to 1% or less at wavelengths ranging from 300 to 360 nm.

Still another aspect is a solar cell module. This solar cell module includes a plurality of solar cells, an encapsulant layered on surfaces of each of the plurality of solar cells, a protective member layered on the encapsulant, and titanium oxide contained between adjacent solar cells among the plurality of solar cells. The encapsulant includes an ultraviolet ray-absorbing member. The ultraviolet ray-absorbing member sets transmittance to 1% or less at wavelengths ranging from 300 to 360 nm.

### BRIEF DESCRIPTION OF THE DRAWINGS

The figures depict one or more implementations in accordance with the present teaching, by way of example only, not by way of limitations. In the figures, like reference numerals refer to the same or similar elements.

FIG. 1 is a top view illustrating a solar cell module according to Example 1.

FIGS. 2A and 2B are a top view and bottom view of a solar cell illustrated in FIG. 1.

FIG. 3 is a cross sectional view of the solar cell module illustrated in FIG. 1.

FIG. 4 is a view illustrating transmittance with respect to epoxy resin contained in a light receiving surface protective film illustrated in FIG. 3.

FIG. 5 is a graph illustrating transmittance with respect to a glass substrate/encapsulant/epoxy resin/encapsulant /glass substrate illustrated in FIG. 3.

FIG. 6 is a graph illustrating another transmittance with respect to the glass substrate/encapsulant/epoxy resin/encapsulant/glass substrate illustrated in FIG. 3.

FIG. 7 is a graph illustrating reflectance with respect to the glass substrate/encapsulant/back sheet illustrated in FIG. 3.

FIG. 8 is a cross sectional view of a solar cell module according to Example 2.

### DETAILED DESCRIPTION

### EXAMPLE 1

Before describing Example of the present invention in detail, a fundamental knowledge will hereinafter be described. Example 1 of the present invention relates to a solar cell module including a plurality of solar cells. A protective film disposed on surfaces of the solar cells contains epoxy resin.

The epoxy resin is degraded by ultraviolet rays. A back sheet also contains resin so that the hack sheet is degraded by the ultraviolet rays as similar to the epoxy resin. To prevent such degradation, conventionally, after the ultraviolet rays passing through a protective member or encapsulant, the ultraviolet rays have been subjected to processes so that transmittance of the ultraviolet rays with respect to the surfaces of the cells is set to 10% or less at a wavelength of 350 nm or less.

On the other hand, in order to prevent the degradation by the ultraviolet ray, it is desirable to decrease transmittance at a wavelength higher than 350 nm. However, in a case of raising a wavelength where transmittance decreases, there is a possibility of decreasing transmittance of visible rays which contributes mainly to photoelectric conversion in the solar cell. Therefore, a material such as the encapsulant has been used conventionally. An object of the present Example is to prevent the decrease in the transmittance of the visible rays, and to decrease the transmittance of the ultraviolet rays so as to prevent a decrease in photoelectric conversion efficiency and to prevent degradation of the resin.

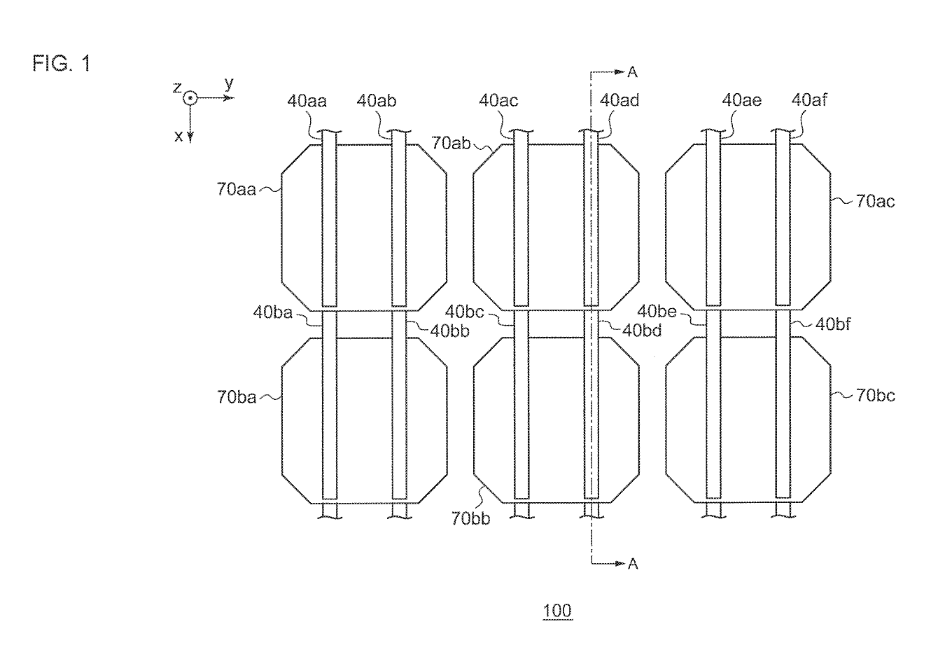

FIG. 1 is a top view illustrating a solar cell module 100 according to Example 1. As illustrated in FIG. 1, Cartesian coordinates including an x-axis, y-axis, and z-axis are defined. The x-axis and y-axis are perpendicular each other in a plane view of the solar cell module 100. The z-axis vertical to the x-axis and y-axis stretches in a thickness direction of the solar cell module 100. Positive directions of the x-axis, y-axis, z-axis are defined by arrows in FIG. 1, and negative directions thereof are defined as directions opposing the arrows. In regard to two main surfaces included in the solar cell module 100 and parallel to an x-y plane, a main plane surface disposed in a positive direction side of the z-axis is a light receiving surface, and a main plane surface disposed in a negative direction side of the z-axis is a back surface. Hereinafter, the positive direction side of the z-axis is called the “light-receiving-surface side” and the negative direction side of the z-axis is called the “back-surface side”.

The solar cell module 100 includes an eleventh solar cell 70aa, twenty-first solar cell 70ba, twelfth solar cell 70ab, twenty-second solar cell 70bb, thirteenth solar cell 70ac, and twenty-third solar cell 70bc collectively called solar cells 70, an eleventh tab wire 40aa, twelfth tab wire 40ab, thirteenth tab wire 40ac, fourteenth tab wire 40ad, fifteenth tab wire 40ae, sixteenth tab wire 40af, twenty-first tab wire 40ba, twenty-second tab wire 40bb, twin third tab wire 40bc, twenty-fourth tab wire 40bd, twenty-fifth tab wire 40be, and twenty-sixth tab wire 40bf collectively called tab wires 40.

A plurality of solar cells 70 is arranged in a matrix in the x-y plane. Herein, two solar cells 70 are arranged in the x-axial direction and three solar cells 70 are arranged in the y-axial direction. It should be noted that the number of the solar cells 70 should not be restricted to six. The plurality of solar cells 70 arranged in the x-axial direction, for example, the eleventh solar cell 70aa and twenty-first solar cell 70ba are connected in series by the twenty-first tab wire 40ba and twenty-second tab wire 40bb so as to form one string. More specifically, the twenty-first tab wire 40ba and twenty-second tab wire 40bb electrically connect a busbar electrode (not illustrated) in the back-surface side of the eleventh solar cell 70aa and a busbar electrode (not illustrated) in the light-receiving-surface side of the twenty-first solar cell 70ba. Other solar cells 70 are also connected in a similar way so as to form other strings. Thus, in FIG. 1, three strings in the x-axial direction are arranged in parallel in the y-axial direction.

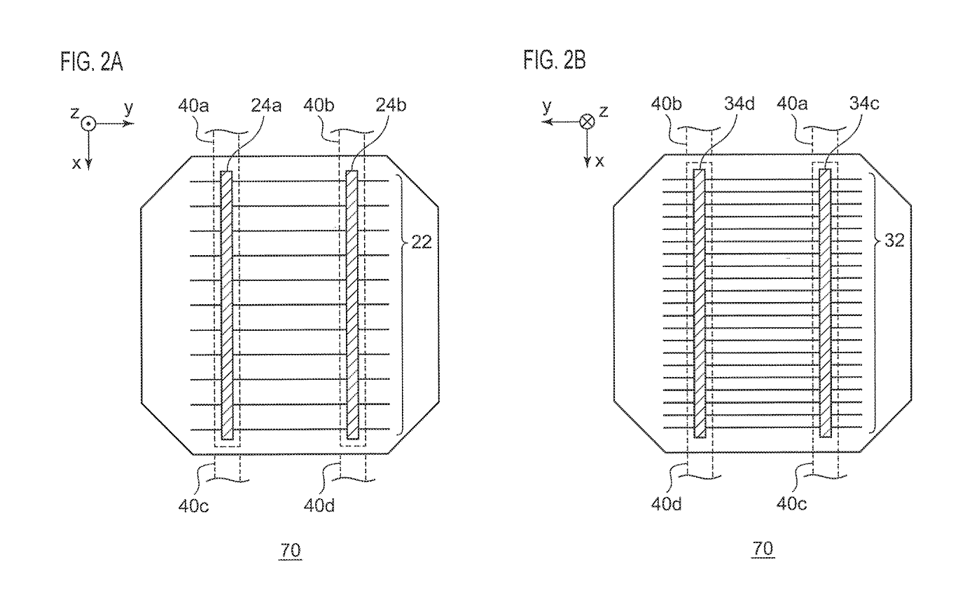

FIGS. 2(a)-(b) are a top view and bottom view of one solar cell 70. FIG. 2(a) is a plane view of the light-receiving-surface side of one solar cell 70. A plurality of finger electrodes 22 is disposed in parallel in the light-receiving-surface side of each solar cell 70. In FIG. 1(a), each finger electrode 22 stretches in the y-axial direction. The finger electrodes 22 collect electric power generated by receiving light. The finger electrodes 22 are formed on the light receiving surfaces so that it is preferable that the finger electrodes 22 are formed thin so as not to shut off the incident light. Furthermore, it is preferable that the finger electrodes 22 are disposed at a predetermined interval so as to collect the generated electric power efficiently.

A plurality of busbar electrodes 24 is also disposed in parallel in the light-receiving-surface side of each solar cell 70. Each busbar electrode 24 is disposed to intersect with or to be perpendicular to each finger electrode 22 so that the plurality of finger electrodes 22 is connected to each other. FIG. 2(a) illustrates a first busbar electrode 24a and second busbar electrode 24b stretching in the x-axial direction as the plurality of busbar electrodes 24. Each busbar electrode 24 is preferably formed thin enough not to shut off the incident light and thick enough to allow the electric power collected from the plurality of finger electrodes 22 to flow efficiently.

A plurality of tab wires 40 is adhered to the light receiving surfaces so as to ensure electric continuity with the busbar electrodes 24. In FIG. 2(a), the first tab wire 40a is connected to the first busbar electrode 24a and the second tab wire 40b is connected to the second busbar electrode 24b. Furthermore, each tab wire 40 is also connected to adjacent solar cells 70 (not illustrated) as mentioned above. In such manners, the tab wires 40 are disposed in the same direction as the busbar electrodes 24.

FIG. 2(b) is a plane view of the back-surface side of one solar cell 70. A plurality of finger electrodes 32 is disposed in parallel in the back-surface side of each solar cell 70. In FIG. 2(b), each finger electrode 32 stretches in the y-axial direction as similar to the finger electrodes 22. It should be noted that the back-surface side is not a surface where sunlight mainly enters. Therefore, the number of the finger electrodes 32 is set to be larger than the number of the finger electrodes 22. Due to such a structure, efficiency of power collection, can be enhanced. It should be noted that the number of the finger electrodes 32 may be equivalent to that of the finger electrodes 22 or may be less than that of the finger electrodes 22. The plurality of busbar electrodes 34 is similar to the plurality of busbar electrodes 24 illustrated in FIG. 2(a). The third tab wire 40c and fourth tab wire 40d are similar to the first tab wire 40a and second tab wire 40b illustrated in FIG. 2(a) so that descriptions regarding those wires will be omitted herein.

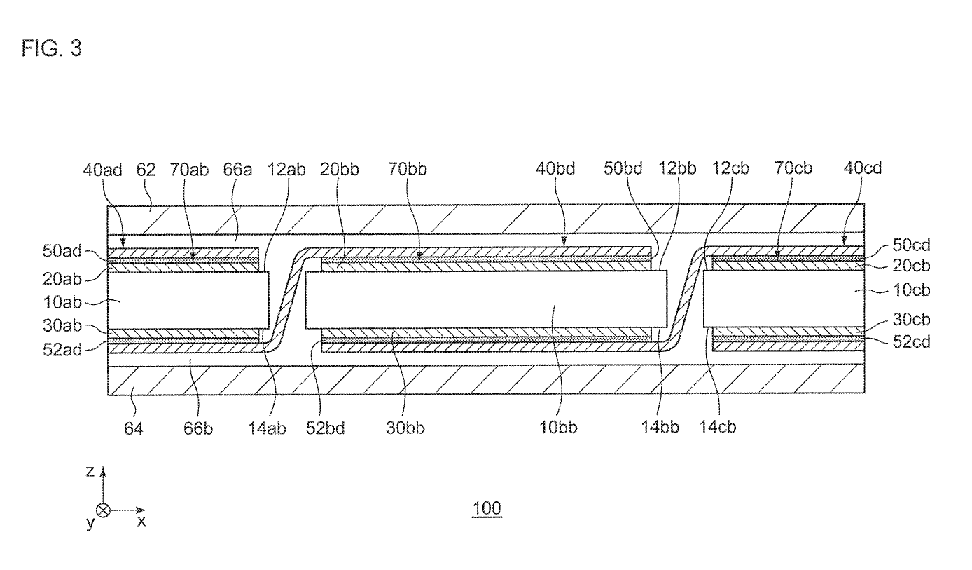

FIG. 3 is a cross sectional view of the solar cell module 100. The view corresponds to a cross sectional view in an A-A direction illustrated in FIG. 1. The solar cell module 100 includes the twelfth solar cell 70ab, the twenty-second solar cell 70bb, and a thirty-second solar cell 70cb collectively called the solar cells 70, the fourteenth tab wire 40ad, the twenty-fourth tab wire 40bd, and a thirty-fourth tab wire 40cd collectively called the tab wires 40, a fourteenth light receiving surface resin layer 50ad, twenty-fourth light receiving surface resin layer 50bd, and thirty-fourth light receiving surface resin layer 50cd collectively called light receiving surface resin layers 50, a fourteenth back surface resin layer 52ad, twenty-fourth back surface resin layer 52bd, and thirty-fourth back surface resin layer 52cd collectively called back surface resin layers 52, a glass substrate 62, a back sheet 64, a first encapsulant 66a and second encapsulant 66b collectively called encapsulants 66.

The twelfth solar cell 70ab includes a twelfth light receiving surface electrode 20ab, a twelfth power-generating layer 10ab, and a twelfth back surface electrode 30ab. The twenty-second solar cell 70bb includes a twenty-second light receiving surface electrode 20bb, a twenty-second power-generating layer 10bb, and a twenty-second back surface electrode 30bb. The thirty-second solar cell 70cb includes a thirty-second light receiving surface electrode 20cb, a thirty-second power-generating layer 10cb, and a thirty-second back surface electrode 30cb. The twelfth fight receiving surface electrode 20ab, twenty-second light receiving surface electrode 20bb, and thirty-second light receiving surface electrode 20cb are collectively called light receiving surface electrodes 20. The twelfth power-generating layer 10ab, twenty-second power-generating layer 10bb, and thirty-second power-generating layer 10cb are collectively called power-generating layers 10. The twelfth back surface electrode 30ab, twenty-second back surface electrode 30bb, and thirty-second back surface electrode 30cb are collectively called back surface electrodes 30.

The power-generating layers 10 absorb the incident light to generate photovoltaic power. Each power-generating layer 10 includes a substrate including a semiconductor material such as crystalline silicon, gallium arsenide (GaAs), and indium phosphide (InP). A structure of each power-generating layer 10 is not restricted. Herein, the photoelectric conversion efficiency of the power-generating layers 10 is mainly higher in wavelengths of the ultraviolet rays than in wavelengths of the visible rays. On the surface in the light-receiving-surface side of each power-generating layer 10, for example, a light receiving surface protective film 12 is disposed to avoid scratches on the surfaces of the solar cells. The light receiving surface protective film 12 is applied to the whole surface of each solar cell 70 to protect the same but is not applied to the tab wires 40. The reason is that an adhesive property of the tab wires 40 should not be influenced by application of the film. The light receiving surface protective film 12 contains epoxy resin. The epoxy resin is a collective term of thermosetting resin capable of being cured by making the same into cross-linked polymer network, with an epoxy group remaining in a high polymer. The epoxy resin before making the same into the cross-linked polymer network is called prepolymer. The prepolymer and a curing agent are mixed and subjected to a thermosetting process so that the epoxy resin can be prepared completely. It should be noted that both the prepolymer and commercialized resin may be called the epoxy resin. Furthermore, a back surface protective film 14 may be disposed on the surface in the back-surface side of each power-generating layer 10. A structure of the back surface protective film 14 may be similar to that of the light receiving surface protective film 12.

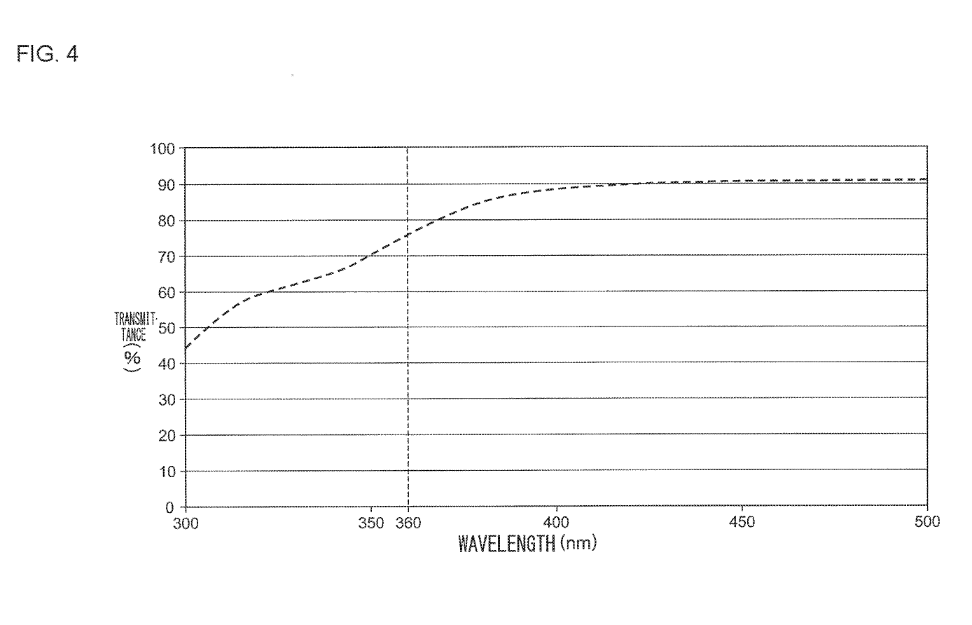

FIG. 4 illustrates transmittance with respect the epoxy resin contained in the light receiving surface protective film 12. A wavelength of light irradiating the epoxy resin is taken along the abscissa and the transmittance is taken along the ordinate. The epoxy resin has transmittance of 80% or more at a wavelength of 370 nm or more. However, when the wavelength becomes lower than the value, the transmittance greatly decreases. Accordingly, it is clear that light having a wavelength about 360 nm or less is absorbed by the epoxy, which causes degradation. Referring back to FIG. 3.

The light receiving surface electrodes 20 include the finger electrodes 22 and busbar electrodes 24 illustrates in FIG. 2(a), and the back surface electrodes 30 includes the finger electrodes 32 and busbar electrodes 34 illustrated in FIG. 2(b). The light receiving surface electrodes 20 are provided to the surfaces in the light-receiving-surface side, while the back surface electrodes 30 are provided to the surfaces in the back-surface side.

The tab wires 40 are adhered to the surfaces by the light receiving surface resin layers 50 or back surface resin layers 52 so as to ensure electric continuity with the light receiving surface electrodes 20 or back surface electrodes 30. Each tab wire 40 is an elongated metallic foil, and an applicable example thereof includes one in which a copper foil is coated with solder or silver and the like. The tab wires 40 are stretching in a direction of the strings. The tab wires 40 connect the light receiving surface electrodes 20 of one of the adjacent solar cells 70 and the back surface electrodes 30 of the other solar cell 70.

The glass substrate 62 is provided to the light-receiving-surface side of the solar cells 70. The glass substrate 62 protects the solar cells 70 from external environment and transmits the light having a wavelength band which is absorbed so that the solar cells 70 can generate electric power. The glass substrate 62 is layered in the light-receiving-surface side of the first encapsulant 66a which is to be mentioned later. It should be noted that the glass substrate 62 may be taken place by polycarbonate, acrylic, polyester, or polyethylene fluoride.

The first encapsulant 66a is provided between the light-receiving-surface side of the solar cells 70 and the glass substrate 62. The first encapsulant 66a is a protective material which prevents penetration of water into the solar cells 70 and to improve intensity of the whole solar cell module 100. The encapsulants 66 have transparency sufficient enough to transmit the sunlight. The encapsulants 66 are, for example, polyolefin such as polyethylene and polypropylene or resin materials such as ethylene-vinyl acetate copolymer (EVA), polyvinyl butyral (PVB), polyimide, and polyethylene terephthalate (PET). As mentioned above, the epoxy resin contained in the light receiving surface protective film 12 is degraded by the ultraviolet rays so that it is desirable that the first encapsulant 66a should not allow the ultraviolet rays to reach, the light receiving surface protective film 12 easily. This corresponds to decreasing the transmittance of the ultraviolet rays in the first encapsulant 66a.

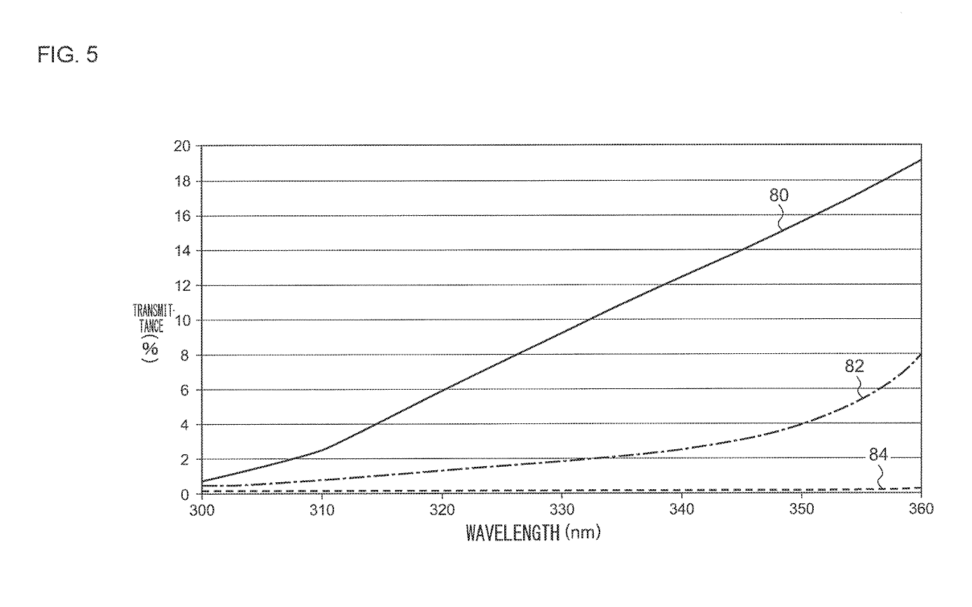

To achieve such a solution, the first encapsulant 66a includes an ultraviolet ray-absorbing member such as an ultraviolet ray-absorbent. It should be noted that the ultraviolet ray-absorbing member may be a wavelength conversion member such as phosphor or may be a combination of the ultraviolet ray-absorbent and wavelength conversion member. Hereinafter, a structure of the ultraviolet ray-absorbent will be described in detail with reference to experimental results with respect to the encapsulants 66. FIG. 5 illustrates the transmittance with respect to the glass substrate 62/encapsulants 66/epoxy resin/encapsulants 66/glass substrate 62. In this experiment, before measurement, those members are irradiated by the ultraviolet rays worth 86 kWh/cm² with cumulative radiant energy of light having wavelengths ranging from 300 to 400 nm. In FIG. 5, the wavelength of the light is taken along the abscissa and the transmittance is taken along the ordinate.

Herein, three types of concentration of the ultraviolet ray-absorbent included in the encapsulants 66 are set. Those types are called a first structure 80, second structure 82, and third structure 84. Those structures are in common with the points that a thickness of each encapsulant 66 is ranging from 200 to 700 μm and that the ultraviolet ray-absorbent included in each encapsulant 66 is benzotriazole. Furthermore, the concentration of the ultraviolet ray-absorbent in the first structure 80 is 0%, which means that the encapsulants 66 do not include the ultraviolet ray-absorbent. The concentration of the ultraviolet ay-absorbent in the second structure 82 is ranging from 0.01 to 0.05%. The concentration of the ultraviolet ray-absorbent in the third structure 84 is ranging from 0.1 to 0.5%. As mentioned before, the epoxy resin is degraded by the light having the wavelength of 360 nm or less.

As illustrated in the graph, in regard to the first structure 80 and second structure 82, the more the wavelength increases from 300 nm to 360 nm, the more the transmittance increases. The transmittance in the first structure 80 is about 19% at the wavelength f 360 nm, and the transmittance in the second structure 82 is about 8% at the wavelength of 360 nm. On the other hand, the transmittance in the third structure 84 is 1% or less at the wavelengths ranging from 300 nm to 360 nm. Therefore, the encapsulants 66 in the third structure 84 do not transmit the ultraviolet rays compared to the encapsulants 66 in the first structure 80 and second structure 82 so that the epoxy resin in the third structure 84 is not subjected to the ultraviolet rays compared to the epoxy resin in the first, structure 80 and second structure 82.

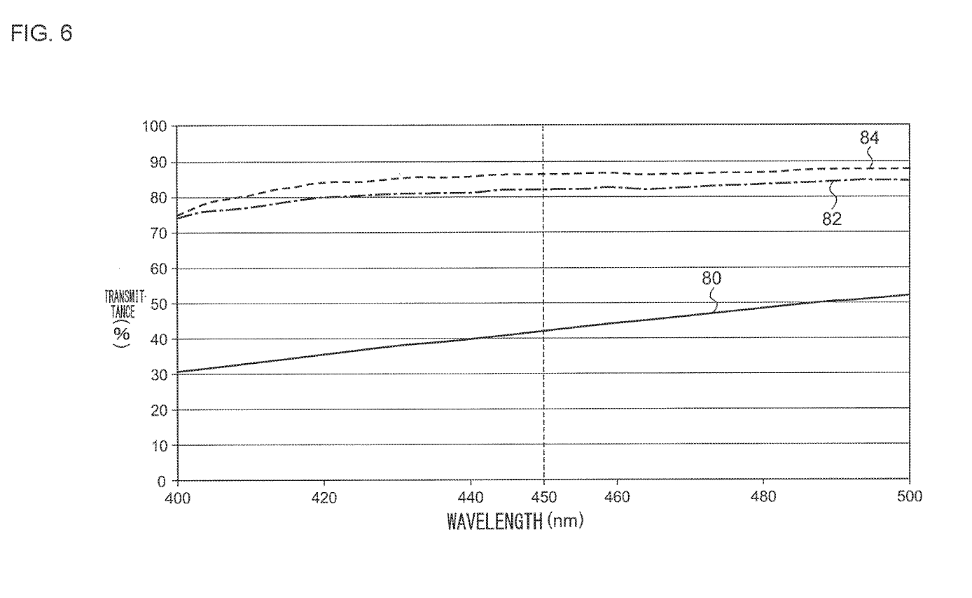

FIG. 6 illustrates the transmittance at wavelengths within a range of 400 nm to 500 nm with respect to the glass substrate 62/encapsulants 66/epoxy resin/encapsulants 66/glass substrate 62. The transmittance gradually decreases in the third structure 84, second structure 82, and first structure 80 in the order mention at the wavelengths ranging from 400 nm to 500 nm. The encapsulants 66 in the first structure 80 transmit the ultraviolet rays more than the encapsulants 56 in the second structure 82 and third structure 84. Therefore, an amount of light of the ultraviolet rays irradiating on the epoxy resin in the first structure 80 becomes large. Accordingly, the epoxy resin is degraded by the ultraviolet ray, which causes yellowing. Thus, the transmittance in the first structure 80 is lower than the transmittance in the second structure 82 and third structure 84 at the wavelengths ranging from 400 nm to 500 nm. Furthermore, when the transmittance within the region decreases, the amount of power generation in the solar cells 70 also decreases.

The encapsulants 66 in the second structure 82 transmit the ultraviolet rays more than the encapsulants 66 in the third structure 84. Therefore, the epoxy resin in the second structure 82 also turns yellow. It should be noted that the degree of yellowing in the second structure 82 is lower than the degree of yellowing in the first structure 80. Therefore, as illustrated in FIG. 6, the transmittance in the second structure 82 increases compared to that of the first structure 80 but decreases compared to that of the third structure 84. The epoxy resin in the third structure 84 is not subjected to the ultraviolet rays compared to the epoxy resin in the first structure 80 and second structure 82 so that shows few signs of yellowing.

Summarizing the above description, in order to prevent degradation of the epoxy resin due to the ultraviolet ray, it is necessary to set the transmittance to 1% or less at the wavelengths ranging from 300 nm to 360 nm. On the other hand, to maintain conversion efficiency as solar cells, it is necessary not to decrease the light entering the cells and not to decrease the transmittance of the visible rays by the ultraviolet ray-absorbent. It is demanded that the transmittance at the wavelength of 450 nm should be set to 80% or more, preferably, 85% or more, and more preferably, 88% or more.

Preferable examples of such an ultraviolet ray-absorbent includes a benzophenone type, benzotriazole type, triazine type, cyanoacrylate type, salicylate type, and acrylonitrile type ultraviolet ray-absorbent. More specifically, 2,2′-methylenebis[6-(2H-benzotriazole-2-yl)-4-(1,1,3,3-tetramethylbutyl)phenol] (Tinuvin 360 manufactured by BASF) or 2-(4,6-diphenyl-1,3,5-triazine-2-yl)-5-[(hexyl)oxy]-phenol (Tinuvin 1577 ED manufactured by BASF) is included as the ultraviolet ray-absorbent. Content of the ultraviolet ray-absorbent is about 5×10⁻⁵ (g/cm²) or more. Referring back to FIG. 3.

The second encapsulant 66b is provided between the back-surface side of the solar cells 70 and the back sheet 64. Therefore, the first encapsulant 66a and second encapsulant 66b are sandwiched by the glass substrate 62 and back sheet 64, and the solar cells 70 are sealed by the first encapsulant 66a and second encapsulant 66b. The structure of the second encapsulant 66b may be different from that of the first encapsulant 66a, but herein they are similar.

The back sheet 64 is layered in the back-surface side of the second encapsulant 66b, opposing the glass substrate 62. The back sheet 64 is formed of PET or formed by sandwiching the epoxy resin with PET. In a case of applying the sandwiched structure, regarding a thickness of the back sheet 64, for example, PET in the light-receiving-surface side is set to 100 μm, the epoxy resin is set from 5 to 30 μm, and PET in the back-surface side is set to 150 μm. Herein, PET is also degraded due to the ultraviolet rays so that the back sheet 64 is also degraded by the ultraviolet rays as similar to the light receiving surface protective film 12. Therefore, it is desirable that the encapsulants 66 should not allow the ultraviolet rays to easily reach the back sheet 64 as well as the light receiving surface protective film 12.

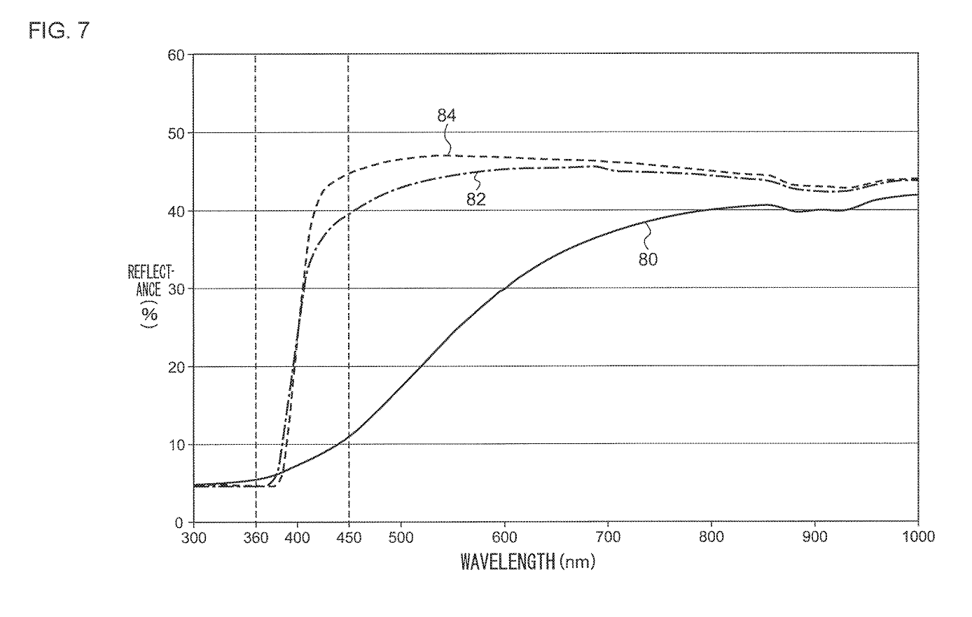

Hereinafter shown are results of an experiment carried out to find whether requirements with respect to the encapsulants 66 are also applicable to the back sheet 64. FIG. 7 illustrates reflectance with respect the glass substrate 62/encapsulants 66/back sheet 64. In this experiment, before measurement, those members are irradiated by the ultraviolet rays worth 86 kWh/cm² with the cumulative radiant energy of the light having the wavelengths ranging from 300 to 400 nm. In FIG. 7, the wavelength of the light ranging from 300 nm to 360 nm is taken along the abscissa and the reflectance is taken along the ordinate. Furthermore, the first structure 80, second structure 82, and third structure 84 illustrated in FIG. 7 are similar to those described above.

In the first structure 80, the transmittance with respect to the encapsulants at the wavelengths ranging from 300 nm to 360 nm increases so that the back sheet 64 turns yellow. Degradation of the back sheet 64 decreases the reflectance of the visible rays with respect to the back sheet. On the other hand, in the third structure 84, the transmittance with respect to the encapsulants at the wavelengths ranging from 300 nm to 360 nm decreases and the reflectance with respect to the visible rays increases. Therefore, in regard to setting the transmittance to 1% or less at the wavelengths ranging from 300 to 360 nm with respect to the ultraviolet ray-absorbent included in the first encapsulant 66a, it is also efficient with respect to the back sheet 64.

As mentioned above, PET is included, for example, in the back sheet 64, first encapsulant 66a, and second encapsulant 66b. The first encapsulant 66a and second encapsulant 66b seal the solar cells 70. During a manufacturing process of the solar cells, the resin such as PET contained in the first encapsulant 66a and second encapsulant 66b flow through the adjacent solar cells 70. Thus, the resin such as PET contained in the first encapsulant 66a and second encapsulant 66b is contained between the adjacent solar cells 70.

Furthermore, the PET may be contained in the light receiving surface protective film 12 so as to be disposed on the surfaces in light-receiving-surface side of the power-generating layers 10. Furthermore, the PET may also be contained in the back surface protective film 14. The PET-containing first encapsulant 66a, second encapsulant 66b, light receiving surface protective film 12, and back surface protective film 14 are also degraded by the ultraviolet rays. Therefore, it is desirable that the encapsulants 66 should not allow the ultraviolet rays to reach those members easily. On the other hand, in regard to setting the transmittance to 1% or less at the wavelengths ranging from 300 to 360 nm with respect to the ultraviolet ray-absorbent included in the first encapsulant 66a, it is also efficient with respect to those members.

According to Example, the encapsulant is disposed on the light receiving surface protective film, and the ultraviolet ray-absorbent included in the encapsulant sets the transmittance to 1% or less at the wavelengths ranging from 300 to 360 nm. Therefore, it is possible to prevent the ultraviolet rays from reaching the light receiving surface protective film. Furthermore, the ultraviolet rays are prevented from reaching the light receiving surface protective film so that it is possible to prevent degradation of the epoxy resin due to the ultraviolet rays. Furthermore, any one of benzophenone type, benzotriazole type, triazine type, cyanoacrylate type, salicylate type, and acrylonitrile type ultraviolet ray-absorbent worth of about 5×10⁻⁵ (g/cm²) is included so that it is possible to set the transmittance to 1% or less at the wavelengths ranging from 300 to 360 nm. Since the transmittance at the wavelength of 450 nm is set to 80% or more, it is possible to prevent the decrease in the photoelectric conversion efficiency of the solar cells.

The encapsulant is disposed in the light-receiving-surface side of the back sheet, and the ultraviolet ray-absorbent included in the encapsulant sets the transmittance to 1% or less at the wavelengths ranging from 300 to 360 nm. Therefore, it is possible to prevent the ultraviolet rays from reaching the back sheet. Since the ultraviolet rays are prevented from reaching the back sheet, it is possible to prevent degradation of the resin contained in the back sheet due to the ultraviolet rays. Since the transmittance at the wavelength of 450 nm is set to 80% or more, it is possible to prevent the decrease in the photoelectric conversion efficiency of the solar cells.

Furthermore, the encapsulant is disposed on the light receiving surface protective film, and the ultraviolet ray-absorbent included in the encapsulant sets the transmittance to 1% or less at the wavelengths ranging from 300 to 360 nm. Therefore, it is possible to prevent the ultraviolet rays from reaching the PET resin-containing member. Since the ultraviolet rays are prevented from reaching the PET resin-containing member, it is possible to prevent degradation of the PET resin due to the ultraviolet rays. Furthermore, the ultraviolet ray-absorbent included in the encapsulant sets the transmittance to 1% or less at the wavelengths ranging from 300 to 360 nm. Therefore, even when the PET resin-containing member is disposed on the surfaces of the solar cells 70, it is possible to prevent degradation of the PET resin due to the ultraviolet rays. Furthermore, the ultraviolet ray-absorbent included in the encapsulant sets the transmittance to 1% or less at the wavelengths ranging from 300 to 360 nm. Therefore, even when the PET resin-containing member is included between the adjacent solar cells 70, it is possible to prevent degradation of the PET resin due to the ultraviolet rays.

A summary of the present Example is as follows. The solar cell module 100 according to an aspect includes the solar cells 70, encapsulants 66 layered on the surfaces of the solar cells 70, glass substrate 62 layered on the encapsulants 66, and epoxy resin-containing light receiving surface protective film 12. Each encapsulant 66 includes the ultraviolet ray-absorbing member. The ultraviolet ray-absorbing member sets the transmittance to 1% or less at the wavelengths ranging from 300 to 360 nm.

The epoxy resin-containing light receiving surface protective film 12 may be disposed on the surfaces of the solar cells 70.

Another aspect is also the solar cell module 100. This solar cell module 100 includes the glass substrate 62, back sheet 64 opposing the glass substrate 62, encapsulants 66 sandwiched between the back sheet 64 and glass substrate 62, and solar cells 70 sealed by the encapsulants 66. The back sheet 64 is formed by including resin, and each encapsulant 66 includes the ultraviolet ray-absorbing member. The ultraviolet ray-absorbing member sets the transmittance to 1% or less at the wavelengths ranging from 300 to 360 nm.

The resin may contain polyethylene terephthalate.

Still another aspect is also the solar cell module 100. The solar cell module 100 includes the solar cells 70, encapsulants 66 layered on the surfaces of the solar cells 70, glass substrate 62 layered on the encapsulants 66, and polyethylene terephthalate resin-containing member. Each encapsulant 66 includes the ultraviolet ray-absorbing member. The ultraviolet ray-absorbing member sets the transmittance to 1% or less at the wavelengths ranging from 300 to 360 nm.

The polyethylene terephthalate resin-containing member may be disposed on the surfaces of the solar cells 70.

The solar cells 70 is included in the plural and the polyethylene terephthalate resin-containing member may be included between the adjacent solar cells 70.

The ultraviolet ray-absorbing member included in each encapsulant 66 may set the transmittance to 80% or more at the wavelength of 450 nm.

Each encapsulant 66 may include at least one of the ultraviolet ray-absorbent or wavelength conversion member.

### EXAMPLE 2

Example 2 will hereinafter be described. Similar to Example 1, Example 2 relates to a solar cell module including a plurality of solar cells. A part of light incident from a light-receiving-surface side is incorporated into the plurality of solar cells, and the remaining light is transmitted through adjacent solar cells. To improve power generation efficiency of such solar cells, it is necessary to make the solar cells incorporate the incident light without transmitting the incident light through adjacent solar cells. In Example 2, to make the solar cells incorporate the light incident through adjacent solar cells, titanium oxide serving as a reflective material is contained between the adjacent solar cells This titanium oxide is degraded by ultraviolet rays as similar epoxy resin and the like. Therefore, an object of Example 2 is also to prevent a decrease in transmittance with respect to visible rays, while decreasing the transmittance with respect to the ultraviolet rays so as to prevent degradation of the photoelectric conversion efficiency and to prevent degradation of the resin. A solar cell module 100 and solar cells 70 according to Example 2 are similar to those types illustrated in FIGS. 1 and 2. Herein, differences between Example 1 will be mainly described.

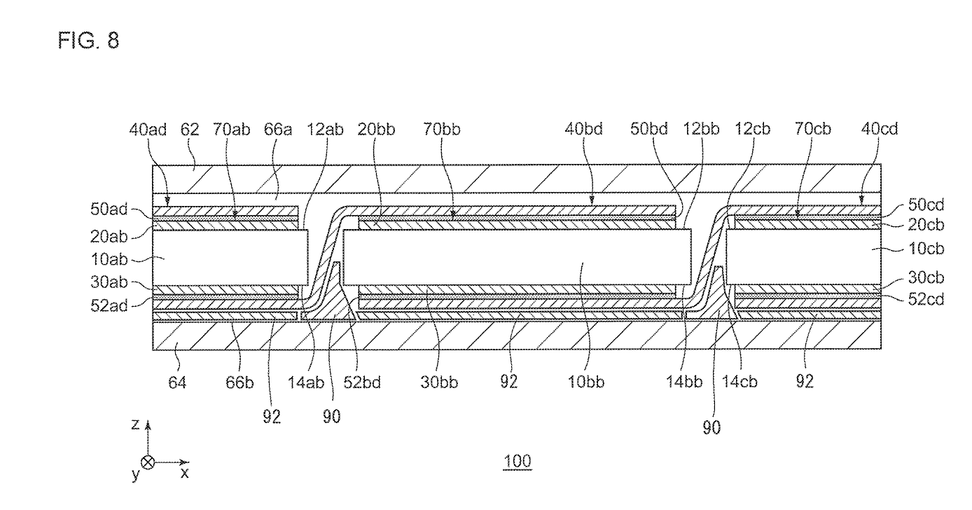

FIG. 8 is a cross sectional view of the solar cell module 100 according to Example 2. In addition to the structure illustrated in FIG. 3, the solar cell module 100 includes a first titanium oxide-containing area 90 and a second titanium oxide-containing area 92. Structures of a glass substrate 62, first encapsulant 66a, tab wires 40, light receiving surface resin layers 50, light receiving surface electrodes 20, power-generating layers 10, back surface electrodes 30, and back surface resin layers 52 are similar to those illustrated in FIG. 3 so that descriptions of those members will be omitted.

With respect to a plurality of solar cells 70, the second encapsulant 66b which is the back surface encapsulant is layered in a side opposing the side where the first encapsulant 66a is layered. The second encapsulant 66b includes the first titanium oxide-containing area 90 and second titanium oxide-containing area 92. The first titanium oxide-containing area 90 and second titanium oxide-containing area 92 are where the titanium oxide is mixed with a resin material included in the second encapsulant 66b. Herein, the first titanium oxide-containing area 90 is disposed between the adjacent solar cells 70. On the other hand, the second titanium oxide-containing area 92 is disposed in the back-surface side of the solar cells 70. It should be noted that the first titanium oxide-containing area 90 and second titanium oxide-containing area 92 may not be distinguished clearly in the second encapsulant 66b, but they will be distinguished herein for convenience sake.

Light transmitted through the adjacent solar cells 70 enters the first titanium oxide-containing area 90. The titanium oxide inside the first titanium oxide-containing area 90 reflects the light. The reflected light is absorbed in the solar cells 70. The light transmitted through the adjacent solar cells 70 also enters the second titanium oxide-containing area 92. The second titanium oxide-containing area 92 reflects the light such as infrared light transmitted through the solar cells 70 by the titanium oxide. The light entering the second titanium oxide-containing area 92 is mainly infrared light, while the light entering the first titanium oxide-containing area 90 includes the ultraviolet light and visible light. Therefore, the titanium oxide is easily degraded in the first titanium oxide-containing area 90 than in the second titanium oxide-containing area 92.

The back sheet 64 is disposed to sandwich the plurality of solar cells 70, opposing the glass substrate 62. The back sheet 64 may contain the titanium oxide. In a case where the second encapsulant 66b is a resin material capable of transmitting sunlight, the light enters from the glass substrate 62 and a part of the light transmitted through the adjacent solar cells 70 reaches the back sheet 64. The titanium oxide inside the back sheet 64 reflects the light. The reflected light is absorbed in the solar cells 70. Such titanium oxide is degraded by the ultraviolet rays. Therefore, the ultraviolet ray-absorbing member included in to the first encapsulant 66a sets the transmittance to 1% or less at the wavelengths ranging from 300 to 360 nm.

According to Example of the present invention, the encapsulant is disposed on the light receiving surface protective film, and the ultraviolet ray-absorbent included in the encapsulant sets the transmittance to 1% or less at the wavelengths ranging from 300 to 360 nm. Therefore, the ultraviolet rays can be prevented from reaching the titanium oxide contained between adjacent solar cells. Since the ultraviolet rays are prevented from reaching the titanium oxide contained between adjacent solar cells, it is possible to prevent degradation of the titanium oxide due to the ultraviolet rays. Furthermore, the titanium oxide is activated by the ultraviolet rays so as to serve as a catalyst, but it is possible to prevent degradation of the encapsulant due to such phenomena. Furthermore, the titanium oxide is contained in the second encapsulant so that the power generation efficiency can be improved. Furthermore, the titanium oxide is contained in the back sheet so that the power generation efficiency can be improved.

A summary of the present Example is as follows. Still another aspect is also the solar cell module 100. The solar cell module 100 includes the plurality of solar cells 70, encapsulants 66 layered on the surfaces of each of the plurality of solar cells 70, glass substrate 62 layered on the encapsulants 66, and titanium oxide contained between adjacent solar cells 70 among the plurality of solar cells 70. Each encapsulant 66 includes the ultraviolet ray-absorbing member. The ultraviolet ray-absorbing member sets the transmittance to 1% or less at the wavelengths ranging from 300 to 360 nm.

With respect to the plurality of solar cells 70, the second encapsulant 66b may also be provided in a side opposing the side where the encapsulants 66 are layered. The titanium oxide is contained in the second encapsulant 66b.

The solar cell module 100 may further include a back sheet 64 disposed to sandwich the plurality of solar cells 70, opposing the glass substrate 62. The titanium oxide is contained in the back sheet 64.

As mentioned above, the present invention has been described with reference to Examples. Examples herein are for illustration purpose and it is obvious to those skilled in the art that combinations of each structural element can be modified variously and that such modifications are also within the range of the present invention.

It should be noted that the present invention should not be restricted to Examples 1 and 2. The present invention is also applicable to the epoxy resin-containing member included in the solar cells 70. For example, the present invention may be applicable to an electrode prepared by curing the same with a Cu-containing paste or an Ag-containing paste. Alternatively, the present invention may be applicable to a resin adhesive and the like.

The present Examples 1 and 2 are configured to have the structure in which the finger electrode and busbar electrode are included in the back-surface side. However, the Examples may have a structure in which the whole back surface is made to be an electrode.

Furthermore, the present Examples 1 and 2 are applicable to monocrystal, multicrystal, amorphous silicon, and heterojunction-type solar cells. A structure of the solar cells is applicable to a back-contact structure, heterojunction structure, and the like.

While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell module comprising:
a solar cell;
an encapsulant layered on a surface of the solar cell;
a protective member layered on the encapsulant; and an epoxy resin-containing member, wherein,
the encapsulant includes an ultraviolet ray-absorbing member, and the ultraviolet ray-absorbing member sets transmittance to 1% or less at wavelengths ranging from 300 to 360 nm.

2. The solar cell module according to claim 1, the epoxy resin-containing member is disposed on the surface of the solar cell.

3. A solar cell module comprising:
a protective member;
a back sheet opposing the protective member;
an encapsulant sandwiched between the back sheet and the protective member; and
a solar cell sealed by the encapsulant, wherein
the back sheet is formed of resin, and
the encapsulant includes an ultraviolet ray-absorbing member, and the ultraviolet ray-absorbing member sets transmittance to 1% or less at wavelengths ranging from 300 to 360 nm.

4. The solar cell module according to claim 3, wherein the resin contains polyethylene terephthalate.

5. A solar cell module comprising:
a solar cell;
an encapsulant layered on a surface of the solar cell;
a protective member layered on the encapsulant; and
a polyethylene terephthalate resin-containing member, wherein
the encapsulant includes an ultraviolet ray-absorbing member, and
the ultraviolet ray-absorbing member sets transmittance to 1% or less at wavelengths ranging from 300 to 360 nm.

6. The solar cell module according to claim 5, wherein the polyethylene terephthalate resin-containing member is disposed on the surface of the solar cell.

7. The solar cell module according to claim 5, wherein the solar cell is provided in the plural, and
the polyethylene terephthalate resin-containing member is disposed between adjacent solar cells.

8. A solar cell module comprising:
a plurality of solar cells;
an encapsulant layered on each surface of the plurality of solar cells;
a protective member layered on the encapsulant; and
titanium oxide contained between adjacent solar cells among the plurality of solar cells, wherein
the encapsulant includes an ultraviolet ray-absorbing member, and the ultraviolet ray-absorbing member sets transmittance to 1% or less at wavelengths ranging from 300 to 360 nm.

9. The solar cell module according to claim 8, further comprising
a back-surface encapsulant layered with respect to the plurality of solar cells in a side opposing the side where the encapsulant is layered, wherein
the titanium oxide is contained in the back-surface encapsulant.

10. The solar cell module according to claim 8, further comprising
a back sheet opposing the protective member and disposed so as to sandwich the plurality of solar cells, wherein
the titanium oxide is contained in the back sheet.

11. The solar cell module according claim 1, where in the ultraviolet ray-absorbing member included in the encapsulant sets transmittance to 80% or more in a wavelength of 450 nm.

12. The solar cell module according to claim 3, where in the ultraviolet ray-absorbing member included in the encapsulant sets transmittance to 80% or more in a wavelength of 450 nm.

13. The solar cell module according to claim 5, where in the ultraviolet ray-absorbing member included in the encapsulant sets transmittance to 80% or more in a wavelength of 450 nm.

14. The solar cell module according to claim 8, where in the ultraviolet ray-absorbing member included in the encapsulant sets transmittance to 80% or more in a wavelength of 450 nm.

15. The solar cell module according to claim 1, wherein the encapsulant includes at least one of an ultraviolet ray-absorbent and a wavelength conversion member as the ultraviolet ray-absorbing member.

16. The solar cell module according to claim 3, wherein the encapsulant includes at least one of an ultraviolet ray-absorbent and a wavelength conversion member as the ultraviolet ray-absorbing member.

17. The solar cell module according to claim 5, wherein the encapsulant includes at least one of an ultraviolet ray-absorbent and a wavelength conversion member as the ultraviolet ray-absorbing member.

18. The solar cell module according to claim 8, wherein the encapsulant includes at least one of an ultraviolet ray-absorbent and a wavelength conversion member as the ultraviolet ray-absorbing member.
